(19) United States
(12) Patent Application Publication
(10) Pub. No.: US 2015/0362544 A1
(43) Pub. Date: Dec. 17, 2015

(54) SYSTEM FOR CONTROLLING AND DETECTING THE INTEGRITY OF AN ELECTRICAL SYSTEM IN A VEHICLE

(71) Applicant: R.A. Phillips Industries, Inc., Santa Fe Springs, CA (US)

(72) Inventor: Adam Bean, Hacienda Heights, CA (US)

(21) Appl. No.: 14/742,515

(22) Filed: Jun. 17, 2015

Related U.S. Application Data
(60) Provisional application No. 62/013,354, filed on Jun. 17, 2014.

(51) Int. Cl. G01R 31/00

(52) U.S. Cl. CPC G01R 31/007

(57) ABSTRACT

A device for controlling and monitoring an electrical system of a vehicle and trailer while the vehicle and trailer are stationary or in motion.

### CROSS-REFERENCED TO RELATED APPLICATIONS

This non-provisional patent application claims the priority to and the benefit of U.S. Provisional Application Ser. No. 62/013,354, filed Jun. 17, 2014, and entitled System for Controlling and Detecting the Integrity of an Electrical System in a Vehicle, the entire contents of which is incorporated herein by reference.

### BACKGROUND

The present invention relates to the field of lighting systems for trucks, trailers, and other motor vehicles.

Trailers that are hitched to, and towed behind, tractors, trucks, or other vehicles have electrical systems that typically include stop lights, turn signals, brake lights, exterior lights, interior lights, and/or other external electrical devices. These devices are often operated using controls at the interior of the vehicle towing the trailer. This may be accomplished electrically by coupling one or more electrical wires from the trailer to corresponding wires of the vehicle used to tow the trailer (e.g., via a plug and socket, such as a 7-way connector). Accordingly, by operating controls of the vehicle (e.g., a brake pedal, a turn signal switch, or another type of switch), a signal may be sent via one or more of the wires of the vehicle through the electrical coupling, and to the corresponding wire(s) of the trailer, thereby enabling the vehicle operator to effectively control circuits or devices of the trailer.

One or more electrical devices in a trailer electrical system may fail for a number of reasons including voltages not being within adequate range to power an electrical device, electrical shorts in one or more external devices or in the electrical wiring, electrical opens caused, for example, by a loose or burned out bulb, loose wiring, corrosion and rust, etc.

A driver/operator of a tractor towing a trailer may not be aware of deterioration of the truck or trailer electrical systems because the operator does not have a direct line-of-sight to many of the trailer's electrical devices (such as a trailer's lighting fixtures) from the cab of the tractor. This can create safety hazards due to inconsistent or non-existent power transmission to components of the trailer. Additionally, the operator of the truck may potentially receive a traffic citation for improperly working equipment.

Currently used lighting/electrical signal testers may be plugged into a cord located at the back of a tractor to test various electrical circuits. For example, a tester may be plugged into a T-way connector coupled to the tractor's electrical system. The operator can then switch on the trailer's lights, for example, and the light tester will indicate whether or not there is a voltage at one or more pins of the electrical connector. However, commonly used circuit testers cannot be used when a tractor-trailer is in motion, as they require that the electrical system of the tractor be disconnected from the electrical system of the trailer. This is due to the hardwiring of the electrical system, which is constantly actively running.

### SUMMARY

Accordingly, to provide better monitoring of the various auxiliary devices coupled to a vehicle's electrical system, embodiments of the present invention control and monitor the various auxiliary devices, such as lights of the trailer's lighting system, individually. Embodiments of the invention may be built into the circuitry of the vehicle's electrical systems. Furthermore, embodiments of the invention may notify the operator of the tractor when a fault is detected in one or more auxiliary devices, and may identify which of the auxiliary devices is faulty. According to embodiments of the present invention, the identification of one or more faulty auxiliary devices may occur while the vehicle is in motion and/or when the vehicle is stopped.

### BRIEF DESCRIPTION OF THE DRAWINGS

The accompanying drawings, together with the specification, illustrate exemplary embodiments of the present invention, and, together with the description, serve to explain aspects of embodiments of the present invention. In the drawings, like reference numerals are used throughout the figures to reference like features and components. The figures are not necessarily drawn to scale. The above and other features and aspects of the present invention will become more apparent by the following detailed description of exemplary embodiments thereof with reference to the attached drawings, in which:

FIG. 1 is a perspective view of a trailer employing an electrical control and monitoring system, according to some illustrative embodiments of the present invention;

FIG. 2 is a schematic diagram of the electrical control and monitoring system of the embodiment shown in FIG. 1 utilizing serially-coupled addressable nodes, according to some illustrative embodiments of the present invention;

FIG. 3 is a schematic diagram of the electrical control and monitoring system of the embodiment shown in FIG. 1 having external devices coupled in a hybrid serial-star formation, according to some illustrative embodiments of the present invention;

FIG. 4 is a schematic diagram of an addressable node of the electrical control and monitoring system of the embodiment shown in FIG. 1, according to some illustrative embodiments of the present invention; and

FIG. 5 is a schematic diagram of a control and monitoring unit interface of the electrical control and monitoring system, according to some illustrative embodiments of the present invention.

### DETAILED DESCRIPTION

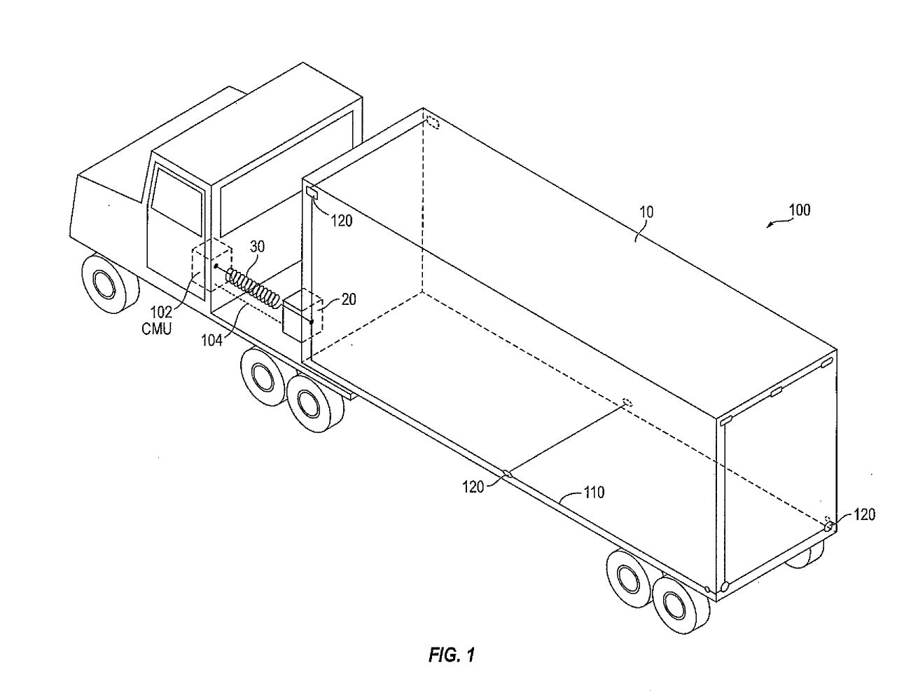

FIG. 1 is a perspective view of a trailer 10 employing an electrical control and monitoring system 100, according to some illustrative embodiments of the present invention.

According to an embodiment of the present invention, the electrical control and monitoring system 100 includes a control and monitoring unit (CMU or a master device) 102, one or more addressable nodes (henceforth, “nodes”) 120 including external devices (e.g. auxiliary devices), and a cable (e.g., multi-conductor cable or electrical harness) 110 for coupling the CMU 102 to the one or more nodes 120. In an embodiment, the CMU 102 is configured to control the state (e.g., the on/off state) of each of the external devices and to monitor the status of each of the external devices to, for example, detect a fault condition at each of the external devices. External devices may include stop lights, turn signals, brake lights, exterior lights, interior lights, and/or other electrical devices external to the tractor, which may be attached to the trailer 10. The CMU 102 may be located in the tractor or the trailer 10. For example, the CMU 102 may be housed in the junction box 20, which is a point of entry or egress of electrical connections to or out of the trailer 10. In an example in which the CMU is inside the tractor, the CMU 102 may be coupled to the cable 110 on the trailer side via either the 7-way connector 30 or a separate external cable 104, which may be an extension of the cable 110 to the tractor.

According to an embodiment, the one or more nodes 120 may be serially coupled to the CMU 102 through the cable 110, which acts as a serial bus connection, and may be addressed individually through the use of unique identifiers (e.g., a digital address) assigned to each of the one or more nodes 120. The CMU 102 may communicate with the one or more nodes 120 using a communication protocol, such as the serial peripheral interface (SPI) protocol, the programmable logic controller (PLC) protocol, the z-wire protocol, and/or the like.

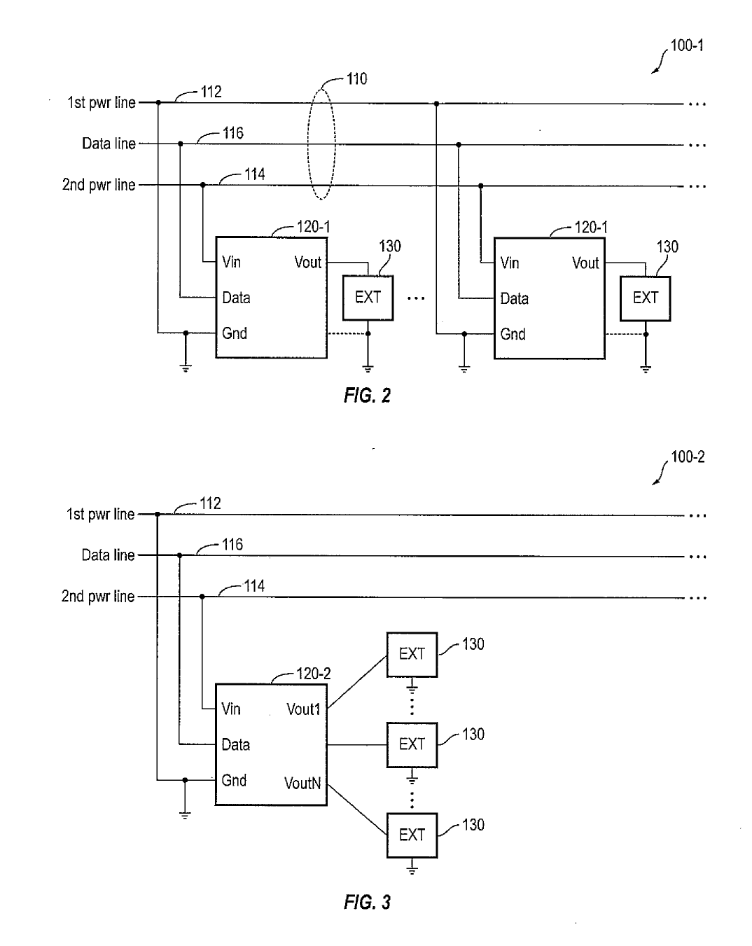

FIG. 2 is a schematic diagram of the electrical control and monitoring system 100-1 of the embodiment shown in FIG. 1 utilizing serially-coupled addressable nodes 120-1, according to some illustrative embodiments of the present invention.

According to an embodiment of the present invention, there is a one-to-one correspondence between nodes 120-1 and external devices 130, that is, each external device 130 may have a corresponding node 120-1 and unique node identifier (e.g., a unique digital address). Each node 120-1 is coupled to the same cable 110 and thus, the nodes 120-1 are serially coupled to the CMU 102.

In some embodiments, the cable 110 may include three or more conducting lines that are electrically coupled to each of the one or more nodes 120-1. For example, the cable 110 may include a first power line (e.g., a ground voltage line) 112, a second power line (e.g., a power voltage line) 114, and a data line 116. The first power line 112 may be electrically coupled to the electrical ground of the trailer 102. The second power line 114 may supply the necessary voltage to power each of the one or more nodes 120-1 and/or the corresponding external devices 130. In an embodiment, the data line 116 may be a bidirectional line that transmits signals from the CMU 102 to the addressable nodes 120-1 and transmits status signals from the nodes 120-1 to the CMU 102. In another embodiment, the data line 116 includes two or more conductive lines for transmitting command and status signals to and from each of the one or more nodes 120-1. The control signal may be a digital or analog signal and may include address data for identifying a target node 120-1, and control data for passing one or more instructions to a target node 120-1.

According to an embodiment, the node 120-1 includes a microcontroller that is programmed with a unique identifier and is programmed to perform one or more processes based on the control signal, when the address data of the control signal matches the microcontroller's unique identifier. Each of the unique identifiers and the address data may be represented with one or more binary bits (e.g., a binary “0” or “1”).

FIG. 3 is a schematic diagram of the electrical control and monitoring system of the embodiment shown in FIG. 1 having external devices 130 coupled in a hybrid serial-star formation, according to some illustrative embodiments of the present invention.

According to an embodiment of the present invention, the nodes 120-2 of the control and monitoring system 100-2 are serially coupled, however, each node 120-2 may be coupled to a plurality of corresponding external devices 130 (in a star formation), with each of the external devices 130 being associated with a unique device identifier (e.g., a unique digital address). Thus, the external devices 130 in the system 102-2 are coupled to the CMU 102 in a hybrid serial-star formation.

In an embodiment, the node 120-2 is a microcontroller that is programmed to respond to the unique identifiers of each of the plurality of external devices 130 coupled to it in a star formation and is programmed to appropriately control a target external device 130 based on the control signal (e.g., the address data embedded in the control signal) received from the CMU 102. The microcontroller may also be programmed to transmit back to the CMU 102 status signals related to the status of each of the plurality of external devices coupled to it with the appropriate address data embedded therein, so that the CMU 102 may identify which, if any, of the external devices has experienced a fault condition.

In other respects, the electrical control and monitoring system 100-2 may be substantially similar to the system 100-1 described above with reference to the embodiments of FIG. 2.

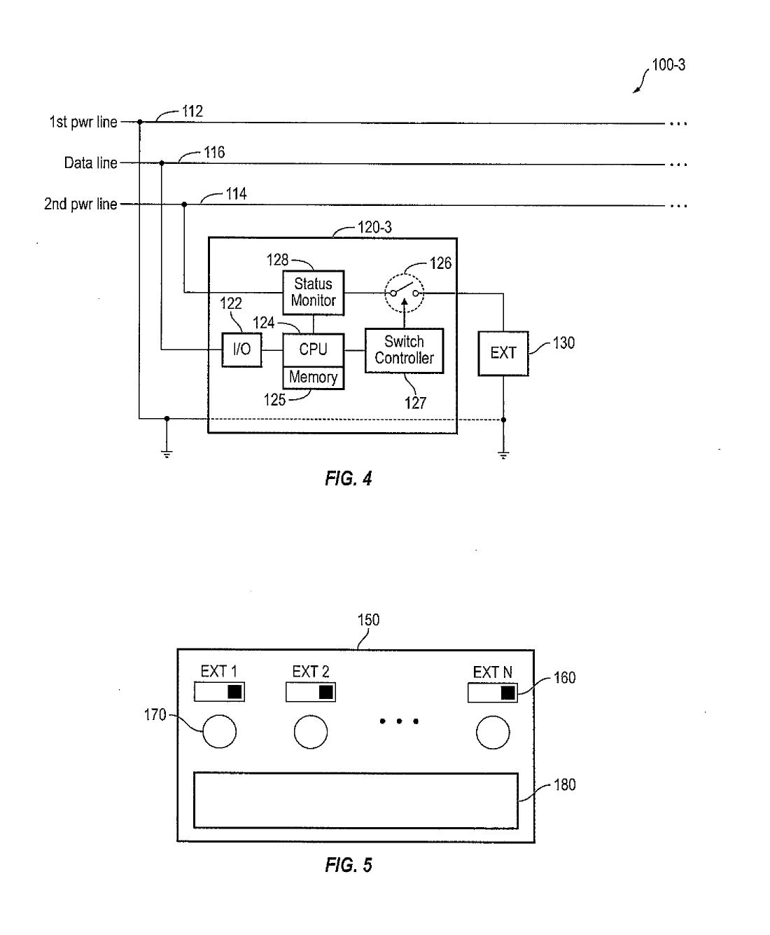

FIG. 4 is a schematic diagram of an addressable node 120-3 in the electrical control and monitoring system 100-3 of the embodiment shown in FIG. 1, according to some illustrative embodiments of the present invention.

According to an embodiment of the present invention, the node 120-3 is a microcontroller including an input/output (I/O) block 122, a central processing unit (CPU) 124, a memory block 125, a status monitor 128, a switch 126, and a switch controller 127. The I/O block 122 may detect the address data embedded in a data signal from the CMU 102 and signals the CPU 124 if the address data matches the unique identifier of one of the one or more external devices (henceforth, the “target device”) 130 coupled to the node 120-3. The CPU 124 then performs an appropriate function based on the control data embedded in the data signal and the instructions stored on the memory 125. For example, the CPU 124 may signal the switch controller 127 to close or open the switch 126, which controls current delivery from the second power line 114 to the target device 130 (and, e.g., turns on or off the target device 130). In another example, the CPU 124 may determine the status of the target device 130 by signaling the status monitor 128 to, for example, measure the current passing through the switch 126, when the switch 126 is in a closed state. In an embodiment, if the measured current is below a lower threshold (e.g., if the current is substantially zero, as may be the case when there is an electrical open) or above an upper threshold (as may be the case if the target device 130 is shorted to ground), the CPU 124 generates (or the CPU 124 in tandem with the I/O block 122 generate) an appropriate status signal indicating a fault signal (and. e.g., the nature of the fault), which identifies the faulty device, to the CMU 102.

In an embodiment, the switch 126 may include a plurality of switches 126 each coupled to one of a plurality of external devices 130 coupled to the node 120-3. The plurality of switches 126. may be individually driven by one or more switch controllers 127.

FIG. 5 is a schematic diagram of a CMU interface 150 coupled to the CMU 102, according to some illustrative embodiments of the present invention.

According to an embodiment, the CMU interface (e.g., a master device interface) 150 includes a dedicated control switch (e.g., on/off switch or button) 160 and/or a dedicated status indicator light 170 for each of the external devices 130, and/or a display screen 180. The operator (e.g., driver) may be able to individually control (e.g., turn on or off) each of the external devices 130 by activating (e.g., toggling) the control switches 160.

In an embodiment, each status indicator light 170 indicates the status of a corresponding external device 130 at any given time, even when the truck is in operation and/or moving. For example, when an external device 130 is functioning normally (e.g., operating as designed), the corresponding status indicator light 170 may appear green, and when the external device 130 becomes faulty (e.g., if an external light goes out), the status indicator light 170 may turn red. However, the invention is not limited thereto, and the status indicator lights 170 may exhibit other modalities, such as, flashing on and off at predetermined frequencies, and/or displaying other colors, depending on the type of fault/error detected.

The display screen 180 may provide further information regarding the status of the external devices 130 and any errors or faults that may have been detected. In one embodiment, upon detection of a fault, the CMU 102 may communicate (e.g., wirelessly communicate) with the carrier to determine the location of nearby truck stops, and may display the location of the nearest truck stop or repair shop on the display screen 180.

What is claimed is:

1. An electrical system for controlling and identifying a state of an electrical device associated with a vehicle, the electrical device being associated with an address, the electrical system comprising:
a control and monitoring unit (CMU) configured to generate a control signal comprising the address, and to identify the state of the electrical device based on a status signal comprising the address;
a node coupled to the electrical device and the CMU, and configured to identify the address based on the control signal, to control the electrical device according to the control signal, and to generate the status signal.

2. The electrical system of claim 1, wherein the node is further configured to detect a fault associated with the electrical device, and to generate a status signal corresponding to the detected fault.

3. The electrical system of claim 1, wherein the CMU comprises an interface configured to display the identified status of the electrical device.

4. The electrical system of claim I, wherein the electrical system further comprises a cable coupling the CMU to the node, the cable being configured to transmit the control signal and the status signal.
